(19) United States
(12) Patent Application Publication
(10) Pub. No.: US 2018/0212607 A1
(43) Pub. Date: Jul. 26, 2018

(54) INTEGRATED CIRCUIT AND ELECTRONIC APPARATUS

(71) Applicant: KABUSHIKI KAISHA TOSHIBA, Minato-ku (JP)

(72) Inventor: Masato ODA, Yokohama (JP)

(73) Assignee: KABUSHIKI KAISHA TOSHIBA, Minato-ku (JP)

(21) Appl. No.: 15/700,793

(22) Filed: Sep. 11, 2017

(30) Foreign Application Priority Data
Jan. 26, 2017 (JP) 2017-012346

(51) Int. Cl. H03K 19/177; H03K 19/173

(52) U.S. Cl. CPC H03K 19/17792; H03K 19/17728; G11C 13/0069; H03K 19/1735; H03K 19/1737; H03K 19/17732

(57) ABSTRACT

An integrated circuit according to an embodiment includes: first through third basic tiles, the second basic tile being located between the first basic tile and the third basic tile, each of the basic tiles including a first logic block configured to perform a logical operation and a first switch block, the first switch block including a first switch circuit, the first switch circuit including: two-terminal switch elements arranged in a matrix form; input terminals, each of the input terminals being connected to one of terminals of each of the two-terminal switch elements aligned in the same column; and output terminals, each of the output terminals being connected to the other one of the terminals of each of the two-terminal switch elements aligned in the same row.

### CROSS REFERENCE TO RELATED APPLICATIONS

This application is based upon and claims the benefit of priority from the prior Japanese Patent Application No. 2017-012346, filed on Jan. 26, 2017, the entire contents of which are incorporated herein by reference.

### FIELD

Embodiments described herein relate generally to integrated circuits and electronic apparatuses.

### BACKGROUND

A field programmable gate array (FPGA) is an integrated circuit that can achieve an appropriate logical function. An FPGA includes logic blocks that perform logical operations, and switch blocks that switch wiring line connections between the logic blocks. Each logic block includes at least one look-up table circuit, and the look-up table circuit outputs a value stored in a memory in accordance with an input. As this memory is rewritten, a wiring line switching function can be implemented in the look-up table circuit.

As will be described later, signal transmission between logic blocks is performed via switch blocks. Therefore, in a case where a signal is transmitted via a large number of switch blocks, a long signal delay is caused.

### BRIEF DESCRIPTION OF THE DRAWINGS

FIG. 1 is a block diagram showing the configuration of an FPGA.

FIG. 2 is a block diagram showing an example configuration of a logical block.

FIG. 3A is a diagram showing an example of a hard macro.

FIG. 3B is a diagram showing another example of a hard macro.

FIG. 4 is a diagram showing an example of a basic tile.

FIG. 5 is a diagram showing an example of a multiplexer.

FIG. 6 is a diagram showing another example of a multiplexer.

FIG. 7 is a diagram showing an FPGA in which three basic tiles are transversely aligned.

FIG. 8 is a diagram for explaining a signal delay in the FPGA shown in FIG. 7.

FIG. 9 is a diagram showing an example of a switch block that solves a signal delay.

FIG. 10 is a diagram showing an FPGA that uses the switch block shown in FIG. 9.

FIGS. 11 and 12 are diagrams for explaining the problem with the FPGA shown in FIG. 10.

FIG. 13 is a circuit diagram showing a basic tile of an integrated circuit according to a first embodiment.

FIG. 14 is a diagram showing the cross-point switch circuit included in a switch block of the first embodiment.

FIG. 15 is a circuit diagram showing an example of a cross-point switch circuit.

FIG. 16 is a circuit diagram showing a switch circuit including write circuits.

FIG. 17 is a diagram for explaining writing in the switch circuit shown in FIG. 16.

FIG. 18 is a circuit diagram showing an integrated circuit according to a first embodiment.

FIG. 19 is a diagram for explaining the effects of the integrated circuit shown in FIG. 18.

FIG. 20 is a circuit diagram showing a integrated circuit according to a first modification of the first embodiment.

FIG. 21 is a circuit diagram showing a integrated circuit according to a second modification of the first embodiment.

FIG. 22 is a circuit diagram showing a integrated circuit according to a third modification of the first embodiment.

FIG. 23 is a block diagram showing an electronic apparatus according to a second embodiment.

### DETAILED DESCRIPTION

An integrated circuit according to an embodiment includes: first through third basic tiles, the second basic tile being located between the first basic tile and the third basic tile, each of the basic tiles including a first logic block configured to perform a logical operation and a first switch block, the first switch block including a first switch circuit, the first switch circuit including: two-terminal switch elements arranged in a matrix form; input terminals, each of the input terminals being connected to one of terminals of each of the two-terminal switch elements aligned in the same column; and output terminals, each of the output terminals being connected to the other one of the terminals of each of the two-terminal switch elements aligned in the same row; a first wiring line connecting the first switch circuit of the first basic tile to the first logic block of the first basic tile; a second wiring line connecting the first switch circuit of the first basic tile to the first switch circuit of the second basic tile; a third wiring line directly connecting the first switch circuit of the first basic tile to the first switch circuit of the third basic tile; a fourth wiring line connecting the first switch circuit of the second basic tile to the first logic block of the second basic tile; a fifth wiring line connecting the first switch circuit of the second basic tile to the first switch circuit of the third basic tile; and a sixth wiring line connecting the first switch circuit of the third basic tile to the first logic block of the third basic tile, wherein the third wiring line is connected to one of the input terminals of the first switch circuit of the second basic tile.

Before embodiments of the present invention are described, the course of events before the present inventor achieved the present invention will be described below.

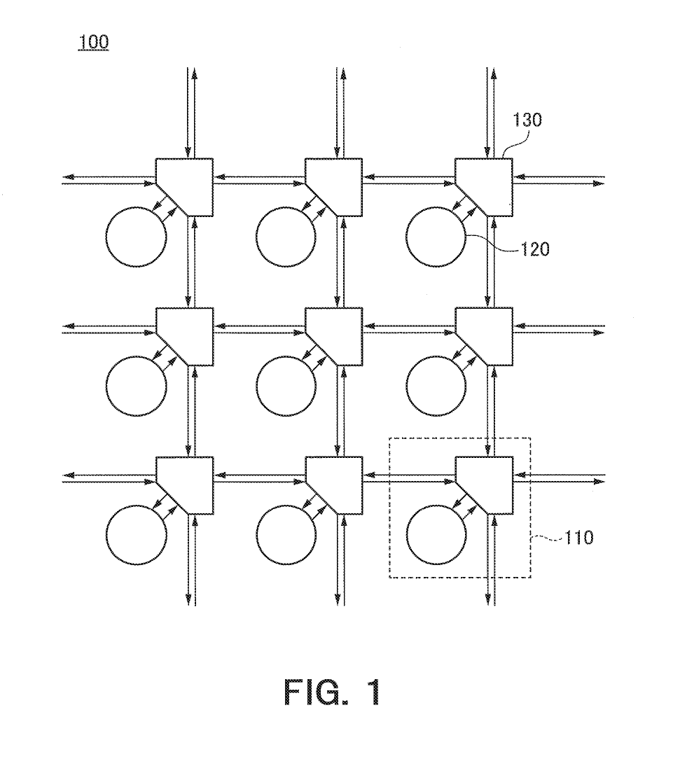

First, the configuration of a typical FPGA is described. As shown in FIG. 1, an FPGA 100 normally includes basic tiles 110 arranged in an array. Each basic tile 110 is connected to adjacent basic tiles 110 by wiring lines. Each basic tile 110 includes a logic block (hereinafter also referred to as LB) 120 and a switch block (hereinafter also referred to as SB) 130. Each logic block 120 is a block that performs a logical operation, and its basic configuration is formed with a look-up table including a truth table. Each switch block 130 controls the connection/disconnection of a wiring line connected to an adjacent basic tile 110 and enables transmission of a signal in any direction.

Also, each switch block 130 connects to each corresponding logic block 120. The logic blocks 120 and the switch blocks 130 can perform connection control in accordance with the data stored in the respective configuration memories.

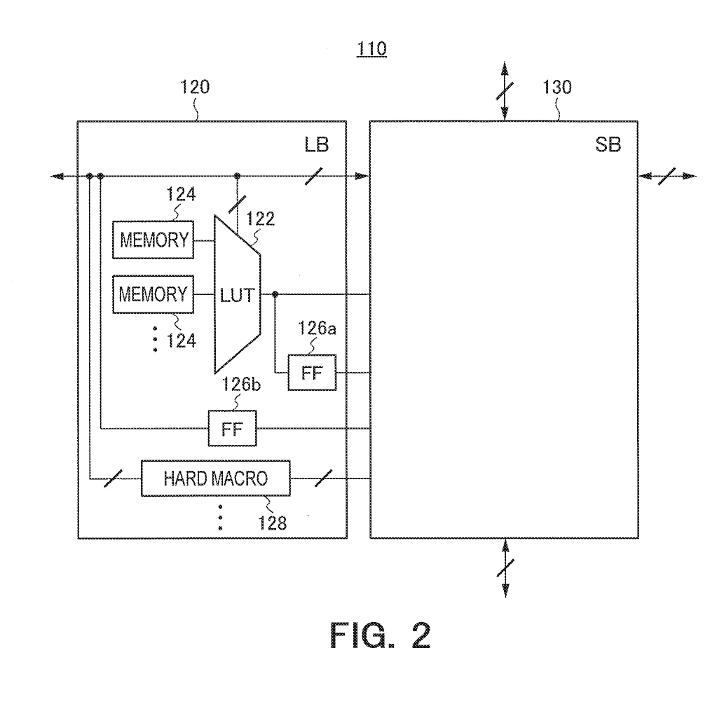

As shown in FIG. 2, each logic block 120 includes a look-up table circuit 122 (hereinafter also referred to as the LUT circuit 122) and memories 124, for example. The LUT circuit 122 outputs information stored in a memory 124, in accordance with an input. It is possible to implement any appropriate function in the LUT circuit 122 by rewriting the information stored in the memory 124.

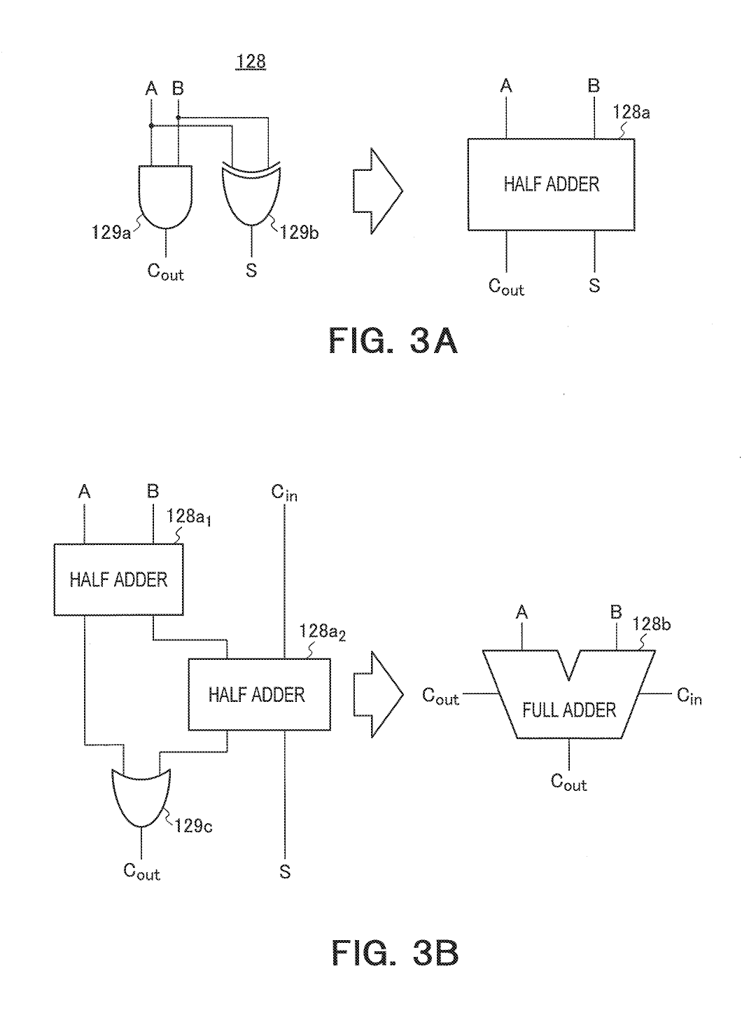

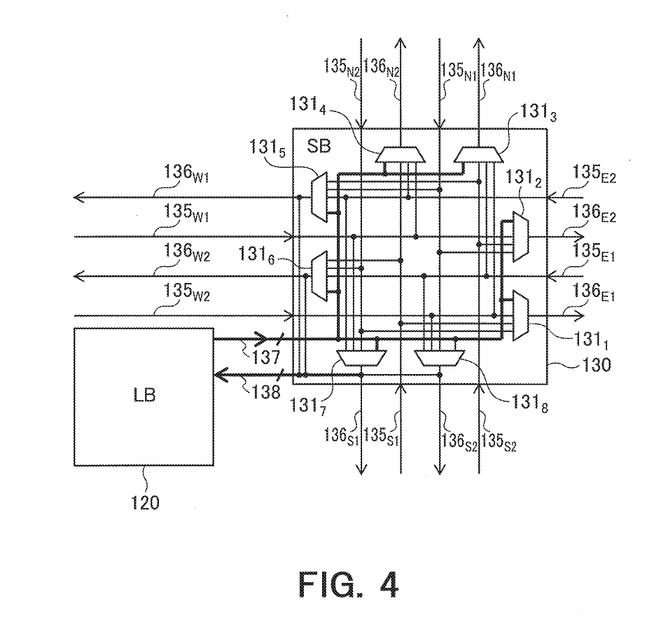

In addition to that, the logic block 120 may include flip flop circuits 126a and 126b, and a hard macro 128. The flip-flop circuit 126a is connected to an output terminal of the LUT circuit 122, and the flip-flop circuit 126b is connected directly to an input terminal of the logic block 120. Here, the hard macro 128 is a group of circuits that are designed in advance. For example, as shown in FIG. 3A, an example of the hard macro 128 is a half adder 128a including an AND gate 129a and an XOR (exclusive OR) gate 129b. Another example of the hard macro 128 is a full adder 128b including half adders 128a₁ and 128a₂, and an OR gate 129c, as shown in FIG. 3B.

Each switch block 130 includes multiplexer circuits (hereinafter also referred to as MUX circuits), for example. Each MUX circuit has a function to select one of the inputs connected thereto, and connect the selected input to an output. The switch block 130 includes the same number of MUX circuits as the number of the output terminals of the switch block 130. Also, the MUX circuits in the switch block 130 are connected to the output terminals of the logic block 120, to connect the output terminals of the logic block 120 to wiring lines. Inputting to the logic block 120 is achieved by inputting one or all of the output terminals of the MUX circuits to the logic block 120.

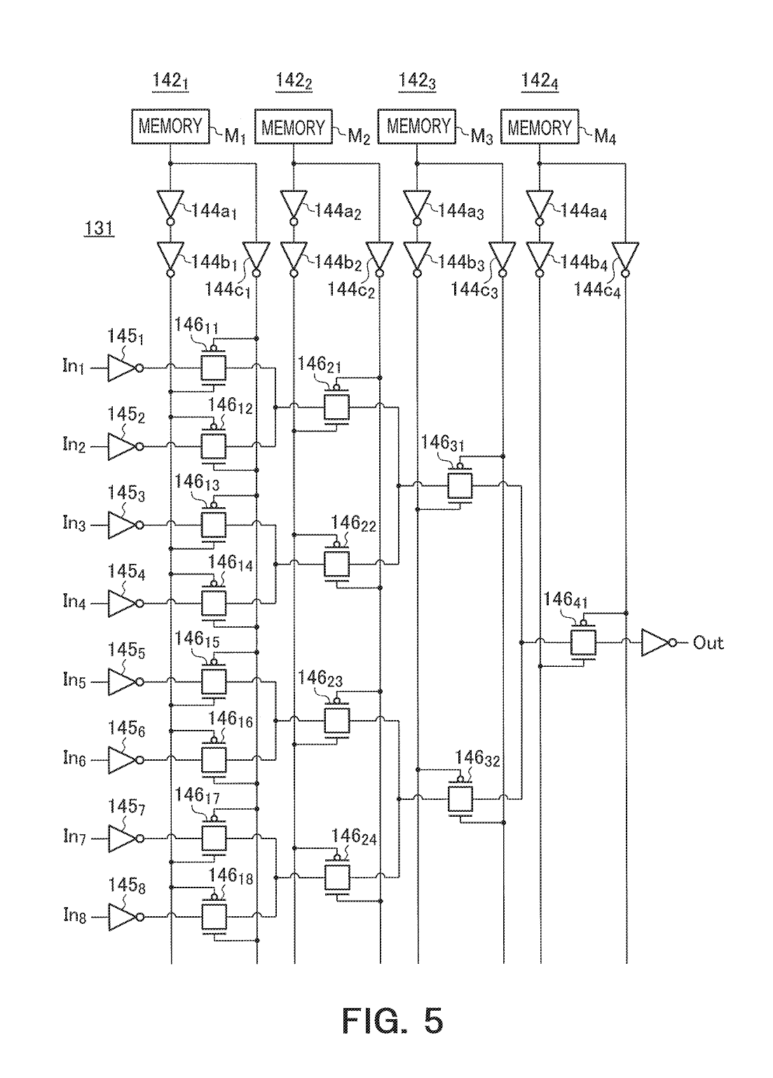

FIG. 4 shows an example of a switch block 130. This switch block 130 includes eight MUX circuits 131₁ through 131₈. The MUX circuits 131₁ through 131₈ each includes input terminals and one output terminal.

The input terminals of the MUX circuit 131₁ are connected to a wiring line group 137 through which signals from the output terminals of the logic block 120 in the same basic tile are transferred, a wiring line 135_{S1} through which a signal input from the lower side is transferred, a wiring line 135_{N2} through which a signal input from the upper side is transferred, and a wiring line 135_{W2} through which a signal input from the left side is transferred, and the output terminal is connected to a wiring line 136_{E1} through which a signal to be transferred to the right side is output.

The input terminals of the MUX circuit 131₂ are connected to the wiring line group 137 through which signals from the output terminals of the logic block 120 in the same basic tile are transferred, a wiring line 135_{S2} through which a signal input from the lower side is transferred, a wiring line 135_{N1} through which a signal input from the upper side is transferred, and a wiring line 135_{W1} through which a signal input from the left side is transferred, and the output terminal is connected to a wiring line 136_{E2} through which a signal to be transferred to the right side is output.

The input terminals of the MUX circuit 131₃ are connected to the wiring line group 137 through which signals from the output terminals of the logic block 120 in the same basic tile are transferred, a wiring line 135_{S2} through which a signal input from the lower side is transferred, a wiring line 135_{E1} through which a signal input from the right side is transferred, and the wiring line 135_{W2} through which a signal input from the left side is transferred, and the output terminal is connected to a wiring line 136_{N1} through which a signal to be transferred to the upper side is output.

The input terminals of the MUX circuit 131₄ are connected to the wiring line group 137 through which signals from the output terminals of the logic block 120 in the same basic tile are transferred, the wiring line 135_{S1} through which a signal input from the lower side is transferred, a wiring line 135_{E2} through which a signal input from the right side is transferred, and the wiring line 135_{W1} through which a signal input from the left side is transferred, and the output terminal is connected to a wiring line 136_{N2} through which a signal to be transferred to the upper side is output.

The input terminals of the MUX circuit 131₅ are connected to the wiring line group 137 through which signals from the output terminals of the logic block 120 in the same basic tile are transferred, the wiring line 135_{E2} through which a signal input from the right side is transferred, the wiring line 135_{N1} through which a signal input from the upper side is transferred, and the wiring line 135_{S2} through which a signal input from the lower side is transferred, and the output terminal is connected to a wiring line 136_{W1} through which a signal to be transferred to the left side is output, and a wiring line 138 extending to an input terminal of the logic block 120.

The input terminals of the MUX circuit 131₆ are connected to the wiring line group 137 through which signals from the output terminals of the logic block 120 in the same basic tile are transferred, the wiring line 135_{E1} through which a signal input from the right side is transferred, the wiring line 135_{N2} through which a signal input from the upper side is transferred, and the wiring line 135_{S1} through which a signal input from the lower side is transferred, and the output terminal is connected to a wiring line 136_{W2} through which a signal to be transferred to the left side is output, and the wiring line 138 extending to an input terminal of the logic block 120.

The input terminals of the MUX circuit 131₇ are connected to the wiring line group 137 through which signals from the output terminals of the logic block 120 in the same basic tile are transferred, the wiring line 135_{E2} through which a signal input from the right side is transferred, the wiring line 135_{N2} through which a signal input from the upper side is transferred, and the wiring line 135_{W1} through which a signal input from the left side is transferred, and the output terminal is connected to a wiring line 136_{S1} through which a signal to be transferred to the lower side is output, and the wiring line 138 extending to an input terminal of the logic block 120.

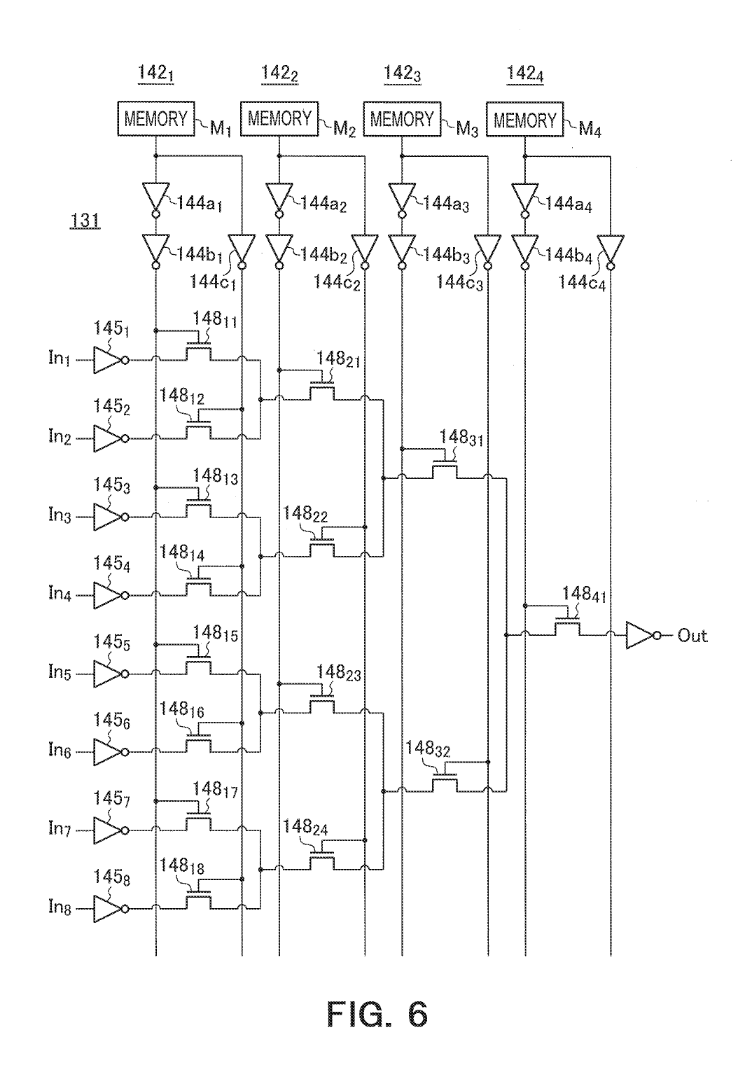

The input terminals of the MUX circuit 131₈ are connected to the wiring line group 137 through which signals from the output terminals of the logic block 120 in the same basic tile are transferred, the wiring line 135_{E1} through which a signal input from the right side is transferred, the wiring line 135_{N1} through which a signal input from the upper side is transferred, and the wiring line 135_{W2} through which a signal input from the left side is transferred, and the output terminal is connected to a wiring line 136_{S2} through which a signal to be transferred to the lower side is output, and the wiring line 138 extending to an input terminal of the logic block 120. Each of these MUX circuits 131 is formed with a CMOS circuit shown in FIG. 5, for example. The MUX circuit 131 shown in FIG. 5 includes four stages of select circuits 142₁ through 142₄, and eight inverters 145₁ through 145₈. Each select circuit 142ᵢ (i=1, 2, 3, 4) includes a memory Mᵢ, three inverters 144aᵢ, 144bᵢ, and 144cᵢ, and 2⁴⁻ⁱ transfer gates 146ᵢⱼ (j=1, . . . , 2⁴⁻ⁱ. Each inverter 145ᵢ (i=1, . . . , 8) receives an input signal Inᵢ at the input terminal.

Each memory Mᵢ (i=1, . . . , 4) stores data “0” or data “1”. Such data is stored into each memory Mᵢ from outside when the FPGA is used. The input terminals of the inverters 144aᵢ and inverters 144cᵢ (i=1, . . . , 4) are connected to the respective memories M. The input terminals of the inverters 144bᵢ (i=1, . . . , 4) are connected to the output terminals of the inverters 144aᵢ.

Each transfer gate 146ᵢⱼ (i=1, . . . , 4, j=1, . . . , 2⁴⁻ⁱ) includes a p-channel MOS transistor and an n-channel MOS transistor connected in parallel.

In the select circuit 142₁, the gate of the p-channel MOS transistor of each of the transfer gates 146₁₁, 146₁₃, 146₁₅, and 146₁₇ is connected to the output terminal of the inverter 144c₁, and the gate of the n-channel MOS transistor is connected to the output terminal of the inverter 144b₁. Also, in the select circuit 142₁, the gate of the p-channel MOS transistor of each of the transfer gates 146₁₂, 146₁₄, 146₁₆, and 146₁₈ is connected to the output terminal of the inverter 144b₁, and the gate of the n-channel MOS transistor is connected to the output terminal of the inverter 144c₁. The input terminals of the respective transfer gates 146₁ⱼ (j=1, . . . , 8) are connected to the output terminals of the inverters 145ⱼ.

In the select circuit 142₂, the gate of the p-channel MOS transistor of each of the transfer gates 146₂₁ and 146₂₃ is connected to the output terminal of the inverter 144c₂, and the gate of the n-channel MOS transistor is connected to the output terminal of the inverter 144b₂. Also, in the select circuit 142₂, the gate of the p-channel MOS transistor of each of the transfer gates 146₂₂ and 146₂₄ is connected to the output terminal of the inverter 144b₂, and the gate of the n-channel MOS transistor is connected to the output terminal of the inverter 144c₂. The input terminals of the respective transfer gates 146₂ⱼ (j=1, . . . , 4) are connected to the output terminals of the transfer gates 146₁₂ⱼ₋₁ through 146₁₂ⱼ.

In the select circuit 142₃, the gate of the p-channel MOS transistor of the transfer gate 146₃₁ is connected to the output terminal of the inverter 144c₃, and the gate of the n-channel MOS transistor is connected to the output terminal of the inverter 144b₃. Also, in the select circuit 142₃, the gate of the p-channel MOS transistor of the transfer gate 146₃₂ is connected to the output terminal of the inverter 144b₃, and the gate of the n-channel MOS transistor is connected to the output terminal of the inverter 144c₃. The input terminals of the respective transfer gates 146₃ⱼ (j=1, 2) are connected to the output terminals of the transfer gates 146₂₂ⱼ₋₁ through 146₂₂ⱼ.

In the select circuit 142₄, the gate of the p-channel MOS transistor of the transfer gate 146₄₁ is connected to the output terminal of the inverter 144c₄, and the gate of the n-channel MOS transistor is connected to the output terminal of the inverter 144b₄. The input terminal of the transfer gate 146₄₁ is connected to the output terminals of the transfer gates 146₃₁ and 146₃₂, and a signal Out is output from the output terminal of the transfer gate 146₄₁.

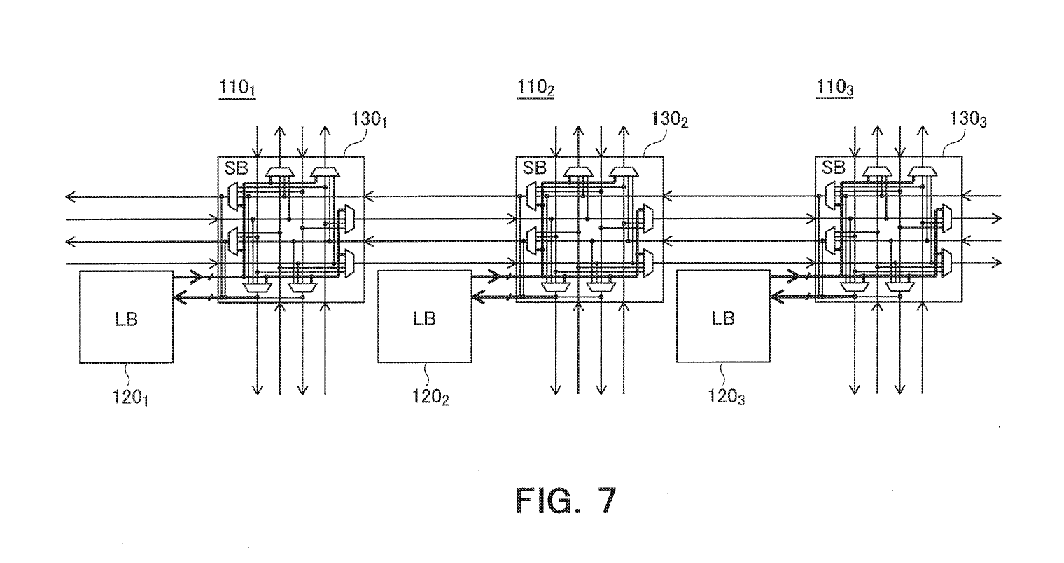

FIG. 6 shows another example of a MUX circuit 131. This MUX circuit 131 has the same configuration as the MUX circuit shown in FIG. 5, except that the transfer gates 146ᵢⱼ (i=1, . . . , 4, j=1, . . . , 2⁴⁻ⁱ) are replaced with n-channel MOS transistors 148ᵢⱼ.

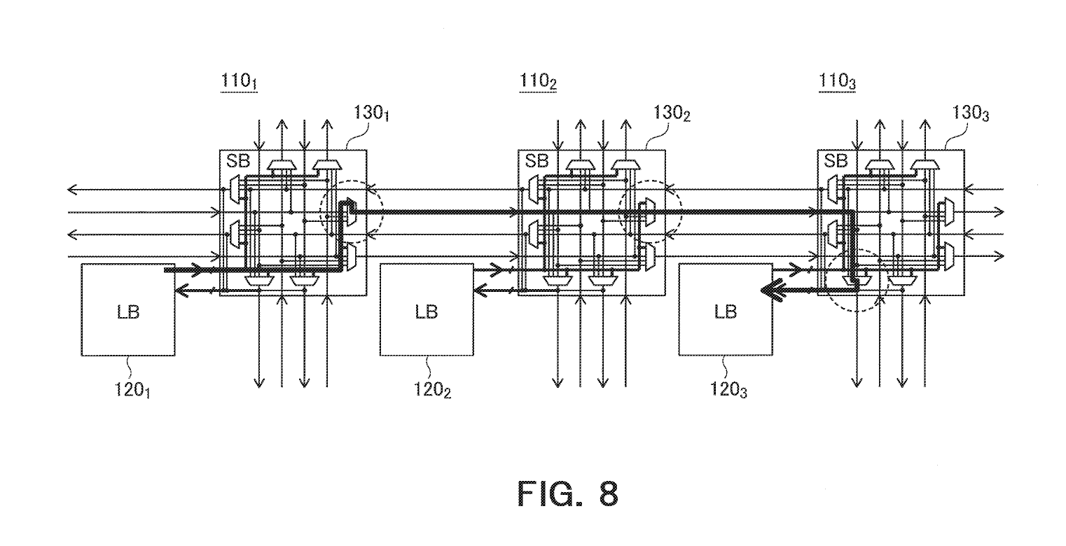

FIG. 7 shows an FPGA in which three basic tiles 110₁, 110₂, and 110₃ are transversely aligned in this order. Each basic tile 110ᵢ (i=1, 2, 3) includes a logic block 120ᵢ and a switch block 130ᵢ. Each switch block 130ᵢ (i=1, 2, 3) has the same configuration as the switch block 130 shown in FIG. 4.

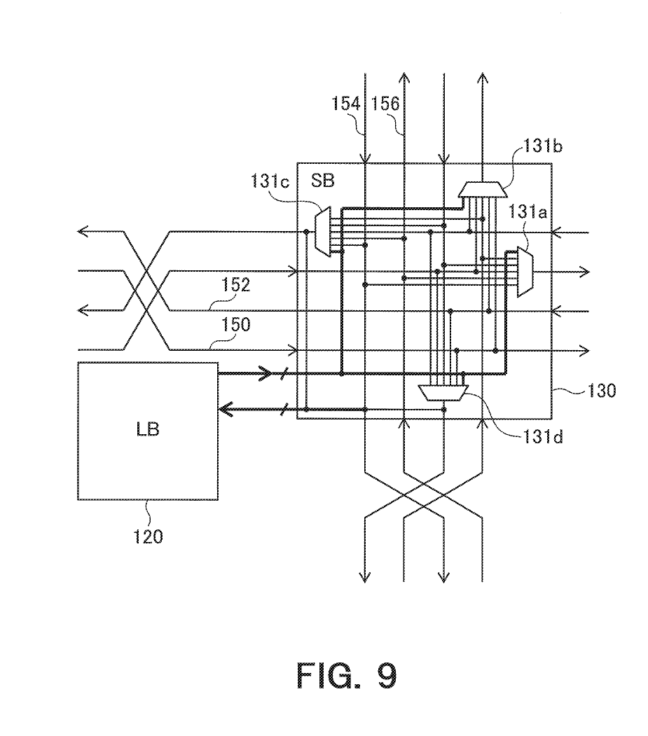

A case where a signal is sent from the logic block 120₁ to the logic block 120₃ in this FPGA is now described. There are several possible paths for sending this signal. However, the shortest route of any of the paths passes through the MUX circuits surrounded by dashed lines in the switch blocks 130₁, 130₂, and 130₃, as indicated by the bold line in FIG. 8. Every time the signal passes through a MUX circuit, a circuit operating delay is added. As shown in this example in FIG. 8, a connection to the next logic block but one does not cause so long a delay. However, in a case where logic blocks at a long distance from each other, such as two logic blocks between which several tens of switch blocks exist, are connected, a long delay is caused.

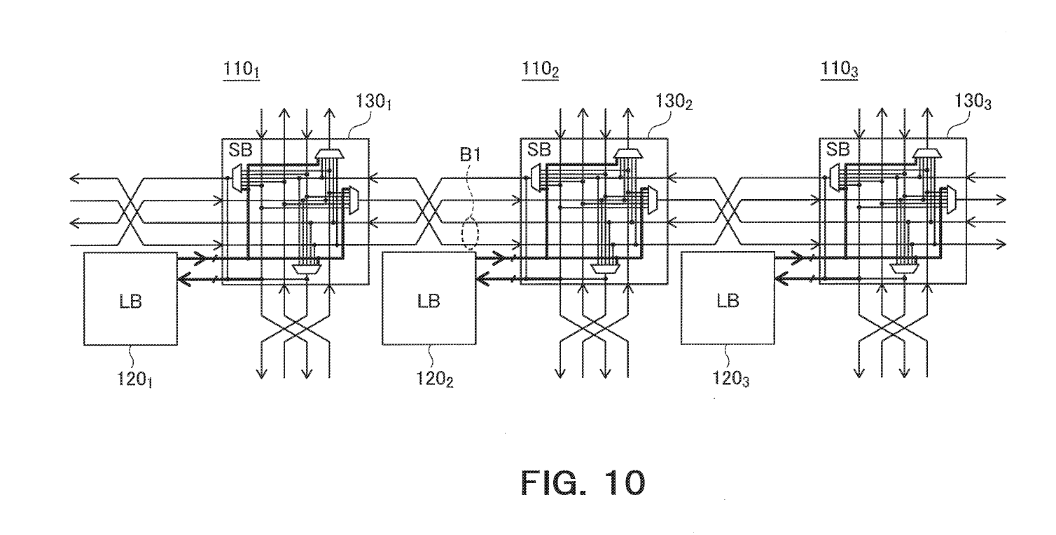

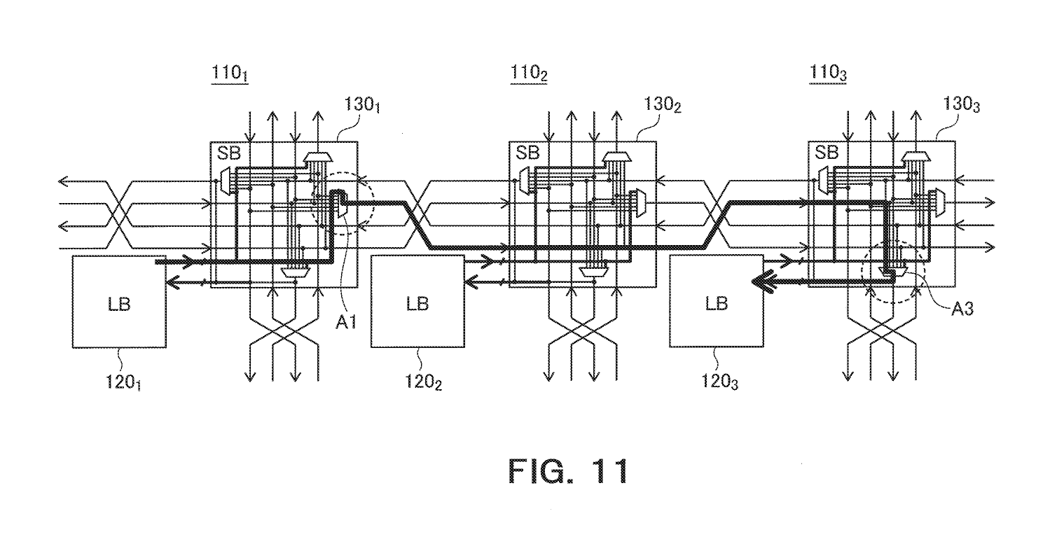

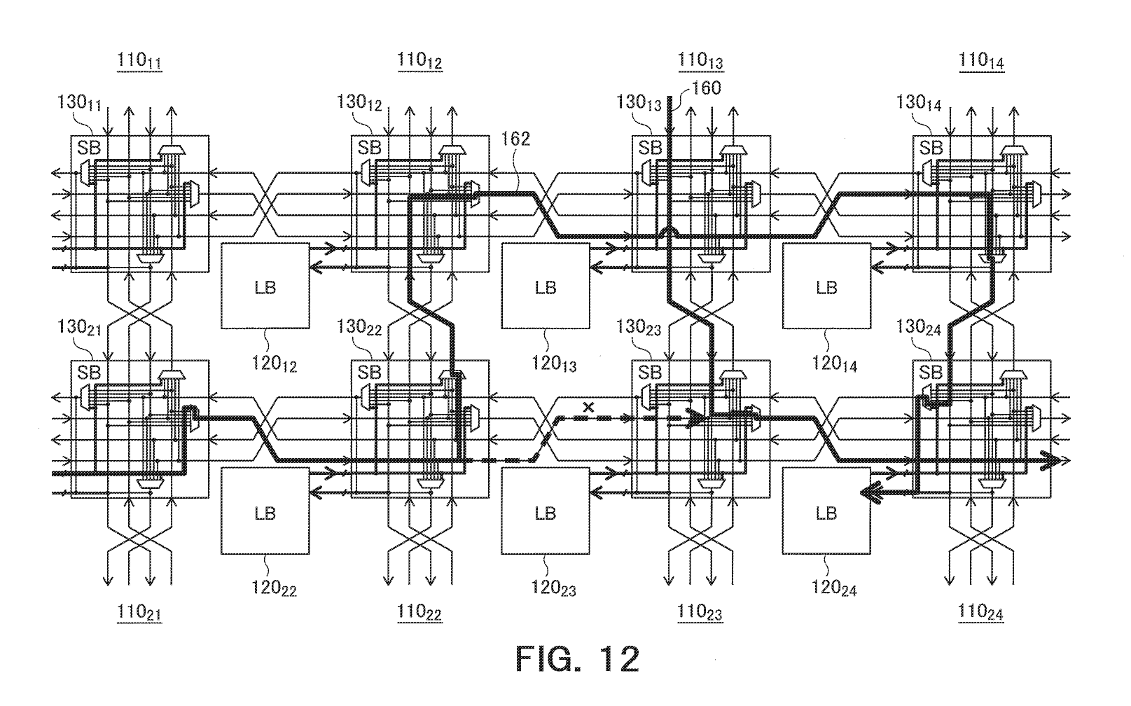

To counter the problem of the delay, there has been a known technique of connecting to a basic tile located at a long distance without passing through any CMOS circuit (any MUX circuit in FIG. 8) in the switch blocks of the adjacent basic tiles (U.S. Pat. No. 5,914,616). According to this technique, a basic tile shown in FIG. 9 is prepared. This basic tile includes wiring lines 150 and 152 that enter MUX circuits 131b and 131d in the switch block 130 but do not pass through MUX circuits 131a and 131c to be connected to adjacent basic tiles, and wiring lines 154 and 156 that enter the MUX circuits 131a and 131c but do not pass through the MUX circuits 131b and 131d to be connected to adjacent basic tiles. FIG. 10 shows an FPGA in which such wiring lines are provided in each basic tile 110ᵢ (i=1, 2, 3). In FIG. 10, the above wiring lines are denoted by reference numeral B1. In this FPGA, the shortest path from the logic block 120₁ to the logic block 120₃ is the path indicated by the bold line in FIG. 11. That is, this shortest path passes through the MUX circuits A1 and A3 surrounded by dashed lines, but does not pass through the other MUX circuits. Accordingly, in a case where wiring lines that connect logic blocks at a long distance from each other (these wiring lines will be hereinafter referred to as long-distance wiring lines) are provided, delays become shorter than those in a case where any long-distance wiring lines are not prepared.

However, not all the paths between logic blocks necessarily have destinations at the ends of long-distance wiring lines. Therefore, an FPGA is designed so that a connection can be established from a long-distance wiring line to a short-distance wiring line, or a connection can established from a switch block through which a long-distance wiring line passes to another long-distance wiring line. However, the area of a MUX circuit or the like greatly increases with an increase in the number of input terminals. Therefore, in a case where MUX circuits are used, connection destinations are normally limited. As can be seen from the circuit shown in FIG. 9, connections other than at the ends are limited to directions perpendicular to the long-distance wiring lines 150 and 152. Any desired wiring lines with limited connection destinations can be provided as above, but the paths might become longer due to the decrease in the degree of freedom in wiring. As shown in FIG. 12, (2×4) basic tiles 110₁₁ through 110₂₄ are arranged in a matrix, and a signal is sent from the logic block 120₂₁ of the basic tile 110₂₁ to the logic block 120₂₄ of the basic tile 110₂₄, for example. In this case, the path connecting the logic block 120₂₁ of the basic tile 110₂₁ to the logic block 120₂₄ via the switch block 130₂₂ of the basic tile 110₂₂, the switch block 130₂₃ of the basic tile 110₂₃, and the switch block 130₂₄ of the basic tile 110₂₄ is normally the shortest. However, if a signal from above the basic tile 110₁₃ is input to the switch block 130₂₃ of the basic tile 110₂₃ through a path 160, another path 162 is used. This path 162 is connected from the logic block 120₂₁ of the basic tile 110₂₁ to the logic block 120₂₄ of the basic tile 110₇₄ via the switch block 130₂₂ of the basic tile 110₂₂, the switch block 130₁₂ of the basic tile 110₁₂, the switch block 130₁₃ of the basic tile 110₁₃, and the switch block 130₁₄ of the basic tile 110₁₄. Therefore, the path 162 extends for a longer distance than in a case where the switch block 130₂₃ of the basic tile 110₂₃ is not used. This will increase not only the delay but also unnecessary paths. As a result, the hardware resources might be consumed, or the number of wiring lines used might be increased.

In view of this, the inventor has made intensive studies, and discovered an integrated circuit that can reduce or prevent the signal delay even when a signal is transmitted via a large number of switch blocks. This integrated circuit will be described below as an embodiment.

The following is a description of embodiments, with reference to the accompanying drawings.

### First Embodiment

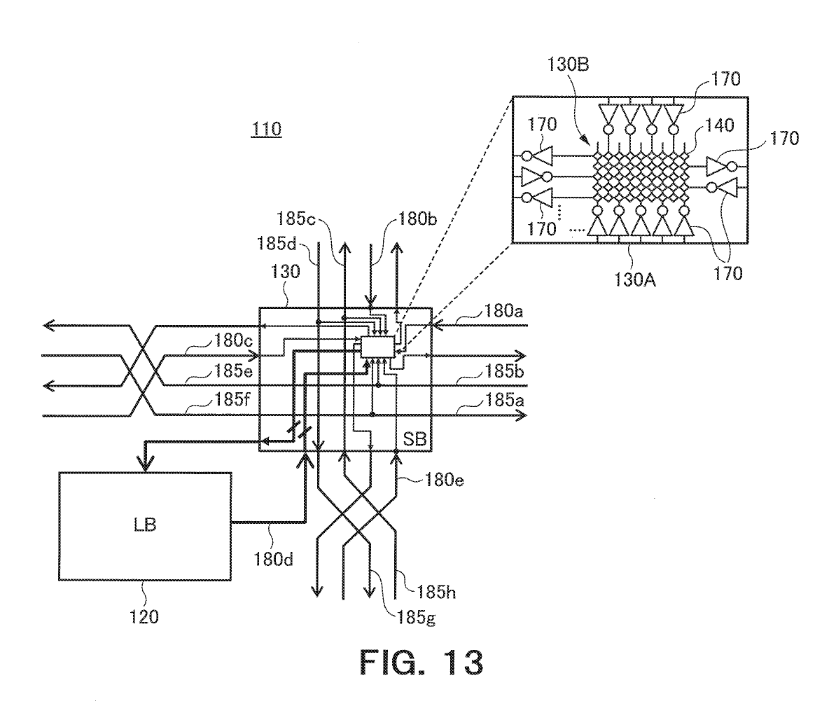

FIG. 13 shows an integrated circuit according to a first embodiment. The integrated circuit of the first embodiment is an FPGA, and includes basic tiles 110 arranged in a matrix as in the case illustrated in FIG. 1. However, only one basic tile is shown in FIG. 13. This basic tile 110 is connected to adjacent basic tiles (now shown) by wiring lines. Each basic tile 110 includes a logic block 120 and a switch block 130.

The switch block 130 of the first embodiment includes a switch circuit 130A.

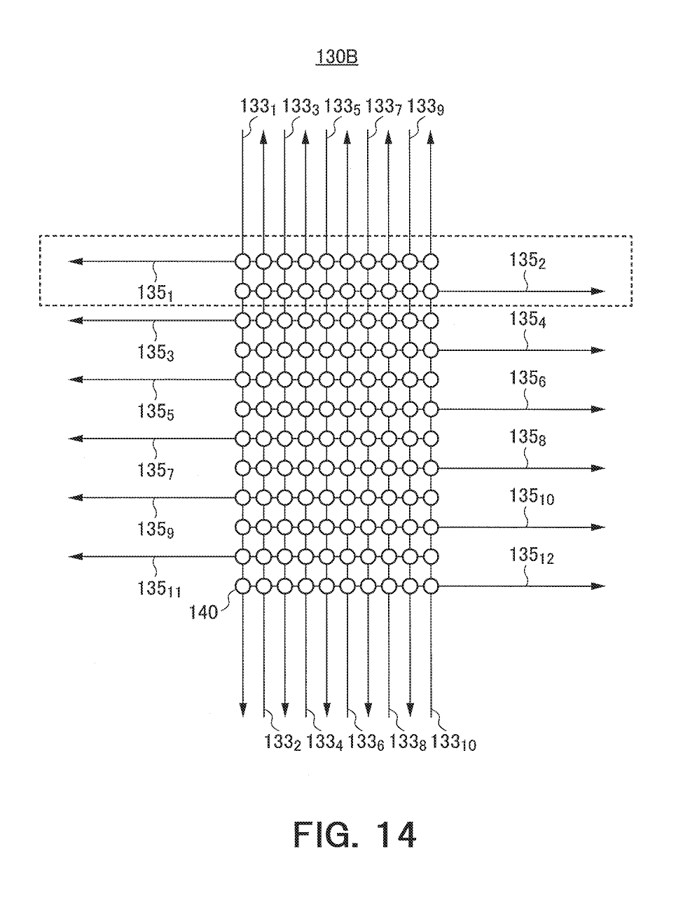

This switch circuit 130A includes a switch circuit 130B shown in FIG. 14, and inverters 170 that are connected to the input wiring lines and the output wiring lines of the switch circuit 130B, and shape a signal waveform. In a case where there is no need to shape a signal waveform, the inverters 170 may not be prepared.

The switch circuit 130A receives all the signals 180a through 180e that are input to the switch block 130, and signals 185a through 185h that are transferred through all the long-distance wiring lines passing through the switch block 130.

The switch circuit 130B shown in FIG. 14 includes switch element circuits 140 arranged in a matrix. The switch element circuits 140 aligned in the same row are connected to one output wiring line (output terminal). For example, in FIG. 14, the switch element circuits 140 aligned in the (2i-1)th row (i=1, . . . , 6) from the top are connected to a row wiring line 135₂ᵢ₋₁ through which a signal is output to the left, and the switch element circuits 140 aligned in the 2ith row are connected to a row wiring line 135₂ᵢ through which a signal is output to the right. The switch element circuits 140 aligned in the (2j-1)th column (j=1, . . . , 5) from the left are connected to a column wiring line 133₂ⱼ₋₁, and the switch element circuits 140 aligned in the 2jth column are connected to a column wiring line 133₂ⱼ. That is, the switch element circuits 140 are provided in the cross regions between wiring lines 133₁ through 133₁₀ and row wiring lines 135₁ through 135₁₂. Each switch element circuit 140 determines the existence/nonexistence of a connection between the corresponding wiring line among the column wiring lines 133₁ through 133₁₀ and the corresponding wiring line among the row wiring lines 135₁ through 135₁₂. It should be noted that the switch element circuits 140 aligned in the first row from the top and the switch element circuits 140 aligned in the second row have the same functions as those of the MUX circuits 131₁ through 131₈ and 131 shown in FIGS. 4 through 6, for example.

In this manner, all the inputs to the switch circuit 130B shown in FIG. 14 can be connected to all the outputs. A switch circuit that includes switch elements circuits arranged in the cross regions between a set of wiring lines and another set of wiring lines, and has all the inputs connectable to all the outputs as above is called a cross-point switch circuit.

In this embodiment, each switch element circuit 140 has a two-terminal switch element.

A two-terminal switch element occupies a smaller area than a MUX circuit, and accordingly, the area occupied by the entire integrated circuit can be made smaller. Each two-terminal switch element may be a variable resistance element such as a magnetic tunnel junction (MTJ) element, a resistive random-access memory (ReRAM) element, an oxidation-reduction resistive change element, an ion-conduction resistive change element, or a phase-change element, or an anti-fuse element such as a gate oxide film breakdown transistor. In this manner, an increase in the area can be prevented.

A ReRAM element (resistive change element) has a structure in which a resistive change layer is interposed between two electrodes. As a voltage is applied between the two electrodes, the electrical resistance of the resistive change layer interposed between the two electrodes changes. A gate oxide film breakdown anti-fuse element is a MOS transistor having a gate oxide film. At least the source or the drain of the anti-fuse element serves as a first terminal, and the gate serves as a second terminal.

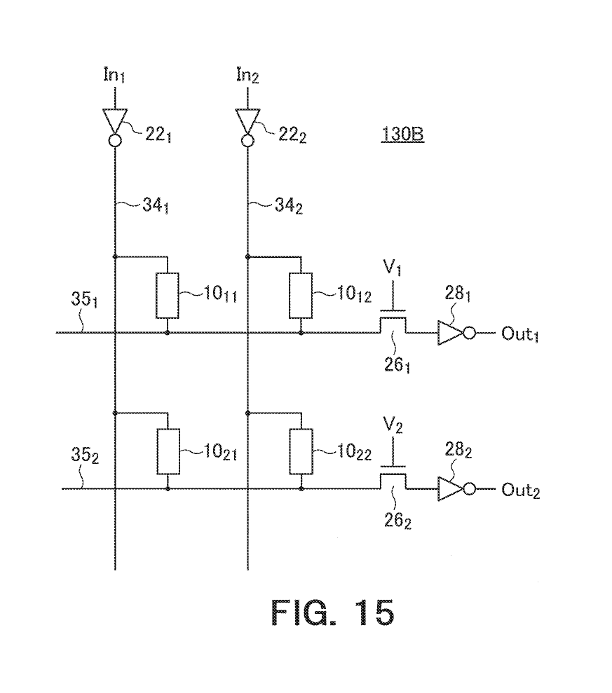

FIG. 15 shows a specific example of a switch circuit 1303 in which two-terminal switch elements are used as switch element circuits 140. The switch circuit 130B of this specific example includes two-terminal switch elements (hereinafter also referred to simply as switch elements) 10₁₁ through 10₂₂ arranged in a (2×2) matrix, inverters 22₁ and 22₂, cutoff transistors 26₁ and 26₂, inverters 28₁ and 28₂, and wiring lines 34₁, 34₂, 35₁, and 35₂.

The wiring lines 34₁ and 34₂ intersect with the wiring lines 35₁ and 35₂. The two-terminal switch elements 10₁₁ through 10₂₂ are disposed in the cross regions between the wiring lines 34₁ and 34₂ and the wiring lines 35₁ and 35₂. The first terminal of each two-terminal switch element 10, (i, j=1, 2) is connected to the wiring line 34ⱼ, and the second terminal is connected to the wiring line 35ᵢ.

Each inverter 22ⱼ (j=1, 2) receives an input signal Inⱼ at the input terminal, and the output terminal thereof is connected to the wiring line 34ⱼ. As for each cutoff transistor 26ᵢ (i=1, 2), one of the source and the drain is connected to the wiring line 35ᵢ, the other one of the source and the drain is connected to the input terminal of the inverter 28ᵢ, and the gate is subjected to a control voltage Vᵢ. An output signal Outᵢ is output from the output terminal of each inverter 28ᵢ (i=1, 2).

In the switch circuit 130B shown in FIG. 15, only one switch element of the two-terminal switch elements aligned in the same row can be put into a low-resistance state.

When input signals In₁ and In₂ are input to the switch circuit 130B having the above configuration, signals corresponding to the resistance states of the switch elements 10₁₁ through 10₂₂ are output as output signals Out₁ and Out₂.

In a case where gate oxide film breakdown anti-fuse elements are used as the switch elements 10ᵢⱼ (i, j=1, 2), if the write voltage of the switch elements 10ᵢⱼ (i, j=1, 2) is higher than the breakdown voltage of the gate oxide films of the anti-fuse elements, the cutoff transistors 26₁ and 26₂ are preferably used for protecting the gate oxide films of the anti-fuse elements on which writing is not being performed. The cutoff transistors 26₁ and 26₂ are also used for protecting the inverters 28₁ and 28₂.

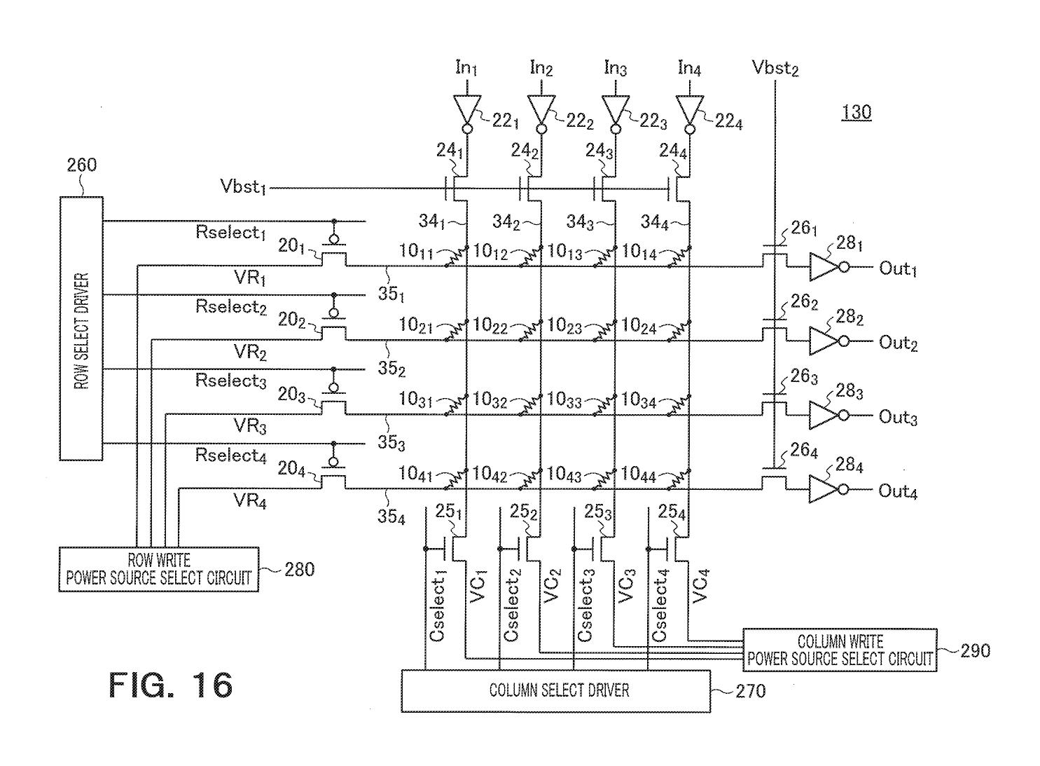

FIG. 16 shows a switch circuit 1308 including write circuits that perform writing on switch elements. The switch circuit 130B shown in FIG. 16 is the same as the switch circuit 130B shown in FIG. 15, except that resistive change elements are used as switch elements arranged in a (4×4) matrix, cutoff transistors 24ⱼ are newly provided between the wiring lines 34ⱼ (j=1, . . . , 4) and the inverters 22ⱼ, and p-channel MOS transistors 20₁ through 20₄ and n-channel MOS transistors 25₁ through 25₄ constituting the write circuits are further provided.

One of the source and the drain (the drain, for example) of each of the transistors 20ᵢ (i=1, . . . , 4) is connected to the corresponding wiring line 35ᵢ, the other one of the source and the drain (the source, for example) is subjected to a write voltage VRᵢ, and the gate receives a row select signal Rselect. One of the source and the drain (the drain, for example) of each of the transistors 25ⱼ (j=1, . . . , 4) is connected to the corresponding wiring line 34ⱼ, the other one of the source and the drain (the source, for example) is subjected to a voltage VCⱼ, and the gate receives a column select signal Cselectⱼ. Each row select signal Rselectᵢ (i=1, . . . , 4) and each column select signal Cselectⱼ (j=1, . . . , 4) are sent from a row select driver 260 and a column select driver 270, respectively. The write voltage VRᵢ (i=1, . . . , 4) is a power source selected by a row write power source select circuit 280, and the write voltage VCⱼ (j=1, . . . , 4) is a power source selected by a column write power source select circuit 290. The write inhibition voltage Vinhibit that will be described later is also given by the row write power source select circuit 280 or the column write power source select circuit 290.

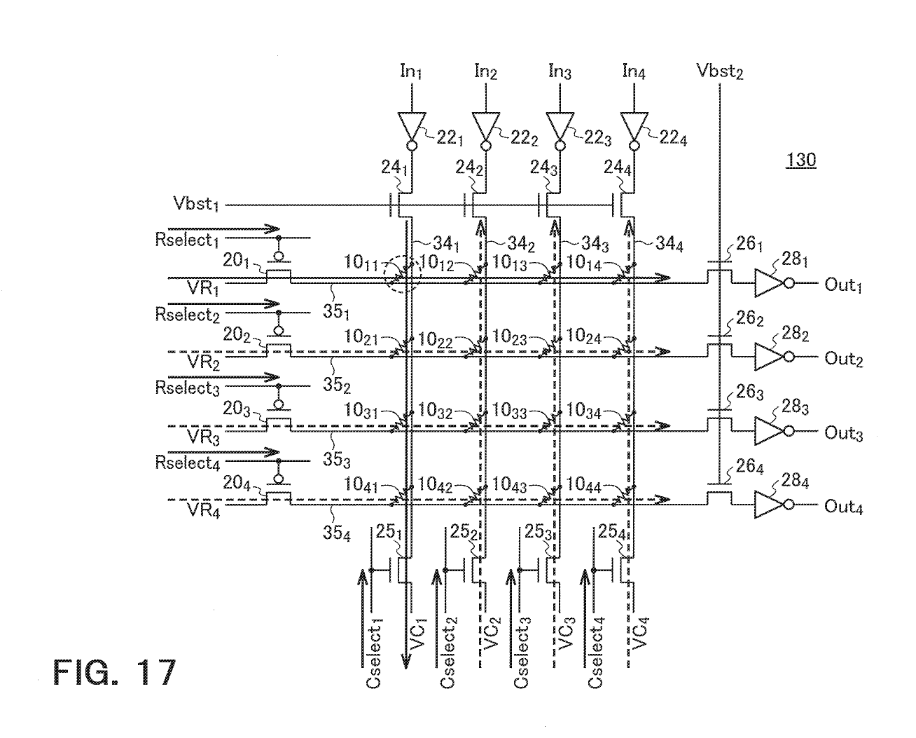

Referring now to FIG. 17, a method of performing writing on the switch circuit 130B having the above described configuration is described. FIG. 17 is a diagram for explaining a method of performing writing on the switch element 10₁₁ indicated by a dashed-line circle.

The writing described herein is an example case where writing is performed on the switch element 10₁₁. A voltage to put the transistor 20₁ into an on-state, such as Vss, is applied as the row select signal Rselect₁, and a voltage to put the transistor 25₁ into an on-state, such as Vdd, is applied as the column select signal Cselect₁. The write voltage VR₁ is then applied to the source of the transistor 20₁ in an on-state, and the voltage VC₁ is applied to the source of the transistor 25₁ in an on-state. This voltage VC₁ is such a voltage that the voltage (=VR₁−VC₁) to be applied between the two terminals of the switch element 10₁₁ becomes higher than the threshold voltage for performing writing on the switch element 10₁₁. That is, the threshold voltage is lower than VR₁−VC₁. With this, writing on the switch element 10₁₁ can be performed. A write inhibition voltage Vinhibit is applied to the two terminals of each of the other switch elements, to prevent wrong writing on any switch element other than the switch element on which writing is to be performed. Here, the write inhibition voltage Vinhibit satisfies the following conditions:

threshold voltage>VR₁−Vinhibit, and

threshold voltage>Vinhibit−VC₁.

Since these voltages leak from the inverters 22₁ through 22₄ on the input side, the transistors 24₁ through 24₄ are necessary. At a time of writing, these transistors 24₁ through 24₄ are put into an off-state, and thus, are disconnected from the inverters 22₁ through 22₄. There is no possibility of the voltages leaking from the inverters 28₁ through 28₄ on the output side, because the gates of the transistors forming these inverters are connected to the wiring lines 35₁ through 35₄. However, in a case where the write voltages VR₁ through VR₄ are higher than the gate breakdown voltages of the transistors forming the above inverters, the inverters 22₁ through 22₄ break due to write operations.

To counter this, the cutoff transistors 26ᵢ (i=1, 2, 3, 4) are provided between the wiring lines 35ᵢ and the inverters 28ᵢ, as shown in FIG. 16. If the potential difference between the signal Vbst₂ applied to the gate and the write voltage VRᵢ (i=1, 2, 3, 4) is smaller than the gate breakdown voltage in each cutoff transistor 26ᵢ, breaking of the gate of the cutoff transistor 26ᵢ can be prevented. Further, where Vth represents the threshold voltage of each cutoff transistor 26ᵢ (i=1, 2, 3, 4), only a voltage Vbst₂−Vth is applied to the inverter 28ᵢ at a maximum. Therefore, if Vbst₂ is lower than the gate breakdown voltage of the transistor forming the inverter 28 (i=1, 2, 3, 4), breaking of the inverter 28ᵢ (i=1, 2, 3, 4) can also be prevented.

As described above, in the integrated circuit of the first embodiment, each switch block 130 includes a cross-point switch circuit 130A. As shown in FIG. 13, this switch circuit 130A receives all the signals 180a through 180e that are input to the switch block 130, and signals 185a through 185h that are transferred through all the long-distance wiring lines passing through the switch block 130. Also, all inputs from the logic block 120 are input to this switch circuit 130A, and the same number of outputs as the number of inputs to the logic block 120 are provided separately from wiring lines. In this manner, a connection to the logic block 120 is established. All the signals 180a through 180e input to the switch block 130 are output in any desired direction, such as a rightward direction, a leftward direction, an upward direction, or a downward direction, via the switch circuit 130A. The signals 185a through 185h transferred through all the long-distance wiring lines passing through the switch block 130 are input to the switch circuit 130A, and are output via other wiring lines in the same direction as the inputs to the switch block 130. That is, signals that are input to the switch block 130 can be output in any desired direction. Thus, the degree of freedom in designing the wiring lines connecting the basic tiles can be increased, and signal delays between logic blocks can be reduced or prevented.

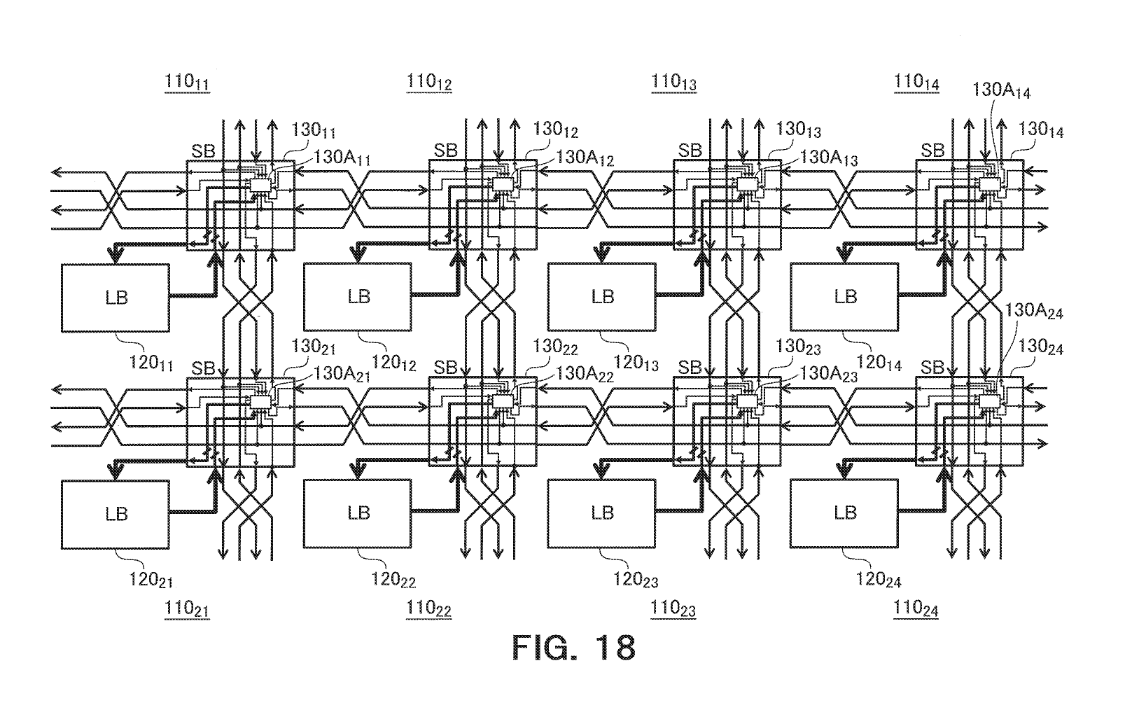

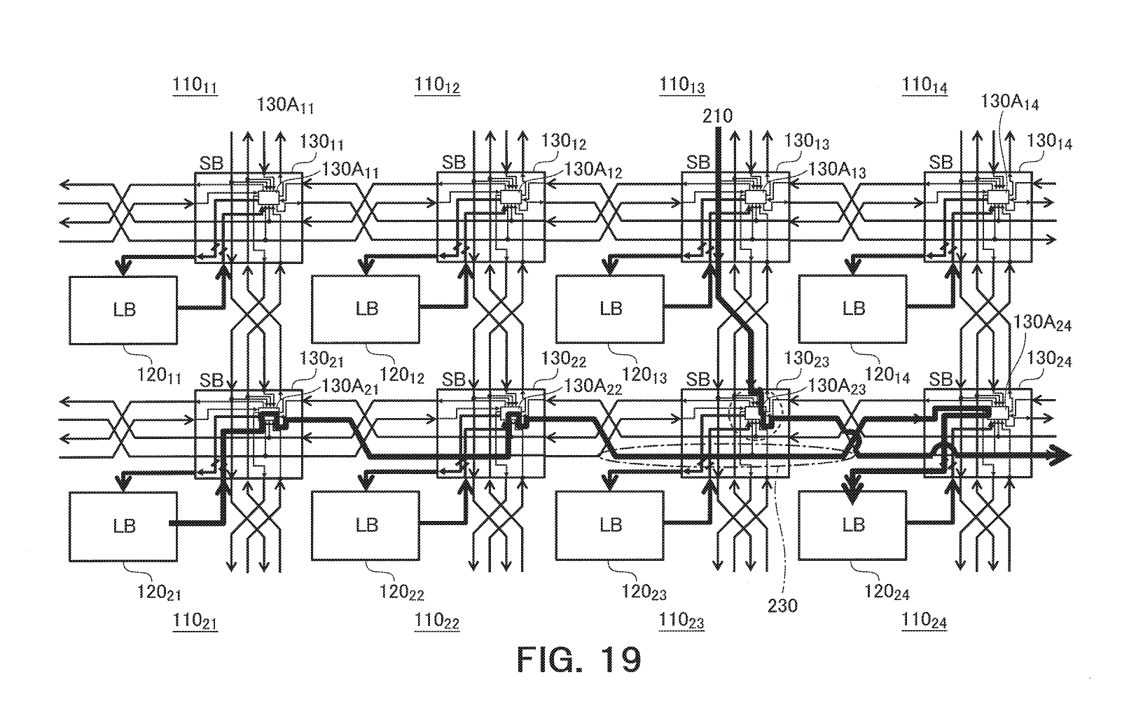

Referring now to FIGS. 18 and 19, the above effects are described in detail. FIG. 18 shows an integrated circuit in which basic tiles that are the same as the basic tile shown in FIG. 13 are arranged in a (2×4) matrix. In each basic tile 110ᵢⱼ (i=1, 2, j=1, . . . 4), the switch block 130 can output the signals input thereto in any desired direction, as in the case described above with reference to FIG. 13. Thus, the degree of freedom in designing the wiring lines connecting the basic tiles can be increased.

FIG. 19 is a diagram for explaining that it is possible to reduce or prevent signal delays between logic blocks in the integrated circuit shown in FIG. 18. Referring to FIG. 19, a case where a signal is sent from the logic block 120₂₁ of the basic tile 110₂₁ to the logic block 120₂₄ of the basic tile 110₂₄ is described. As indicated by a path 210, a signal that is input from above the basic tile 110₁₃ and passes through the switch block 130₁₃ of the basic tile 110₁₃ is input to the switch block 130₂₃ of the basic tile 110₂₃. In this case, the switch block 130₂₃ cannot be used to access the target logic block 120₂₄ to be connected, and the path takes a detour in a conventional integrated circuit, as described above with reference to FIG. 12.

In this embodiment, on the other hand, each switch block includes a cross-point switch circuit 130A, and a signal that is input to the switch block 130 can be output from any desired output terminal of the switch circuit 130A. Therefore, as shown in FIG. 19, a path 230 is formed to send a signal from the logic block 120₂₁ of the basic tile 110₂₁ to the logic block 120₂₄ via the switch block 130₂₁, the switch block 130₂₂ of the basic tile 110₂₂, the switch block 130₂₃ of the basic tile 110₂₃, and the switch block 130₂₄ of the basic tile 110₂₄. That is, as shown in FIG. 19, it is possible to connect to the switch block 130₂₂ before reaching the switch block 130₂₃ in the long-distance wiring line, and “switch” to another long-distance wiring line in the same direction. In this manner, the wiring path does not need to take a detour, and a delay in the path is reduced. Also, the wiring line 230, which is not used in the above described case, can be used, and the number of wiring lines to be used can be reduced. Although only one long-distance wiring line is shown in each direction in FIG. 19, more than one long-distance wiring line may exist in each direction, and, in such a case, the same effects as above can be achieved.

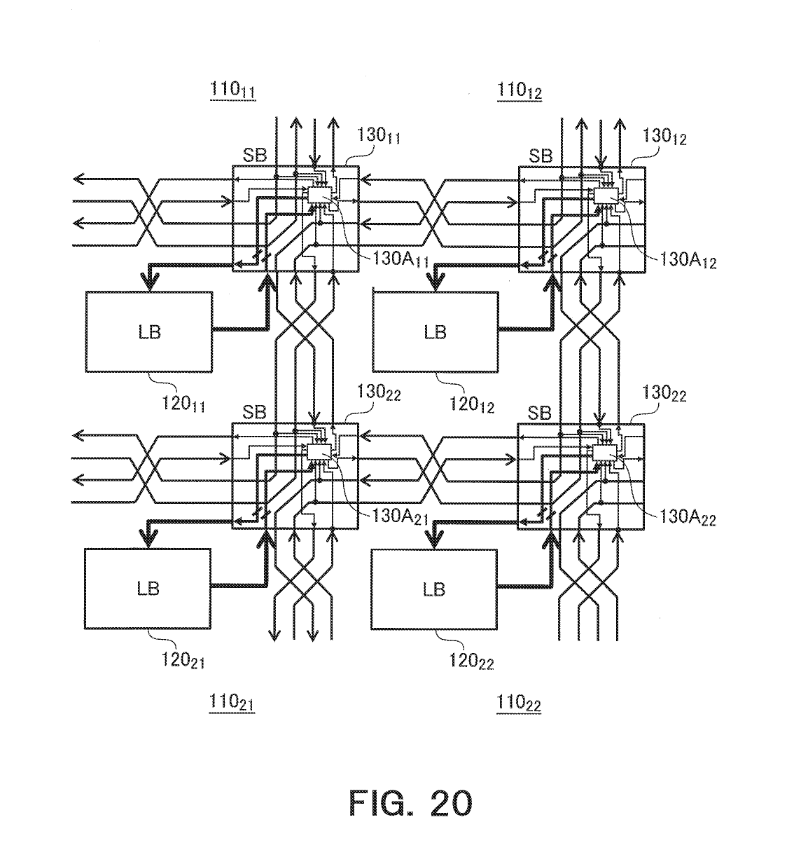

In an integrated circuit of a first modification shown in FIG. 20, a signal is sent through the switch blocks 130₁₁ through 130₂₂ in a direction perpendicular to the direction in which the signal is input. Even if the path is bent unlike the path shown in FIG. 19, the same effects can be achieved, as long as the relation of connection is the same as that shown in FIG. 19. FIG. 20 is a circuit diagram showing an integrated circuit according to a modification of the first embodiment.

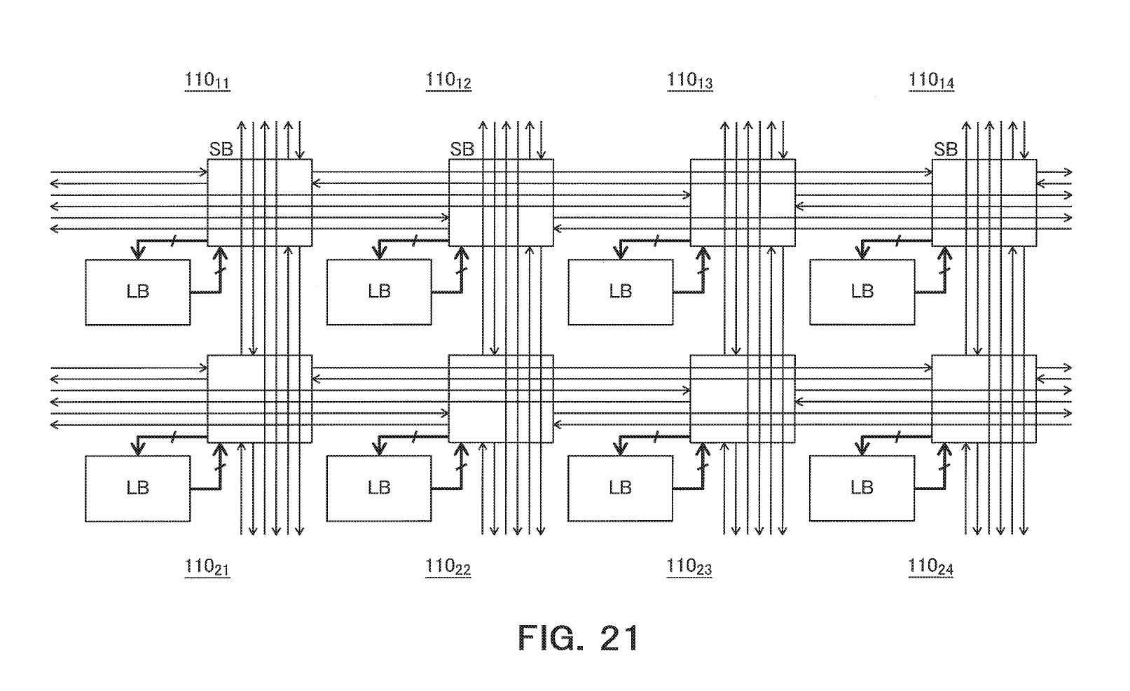

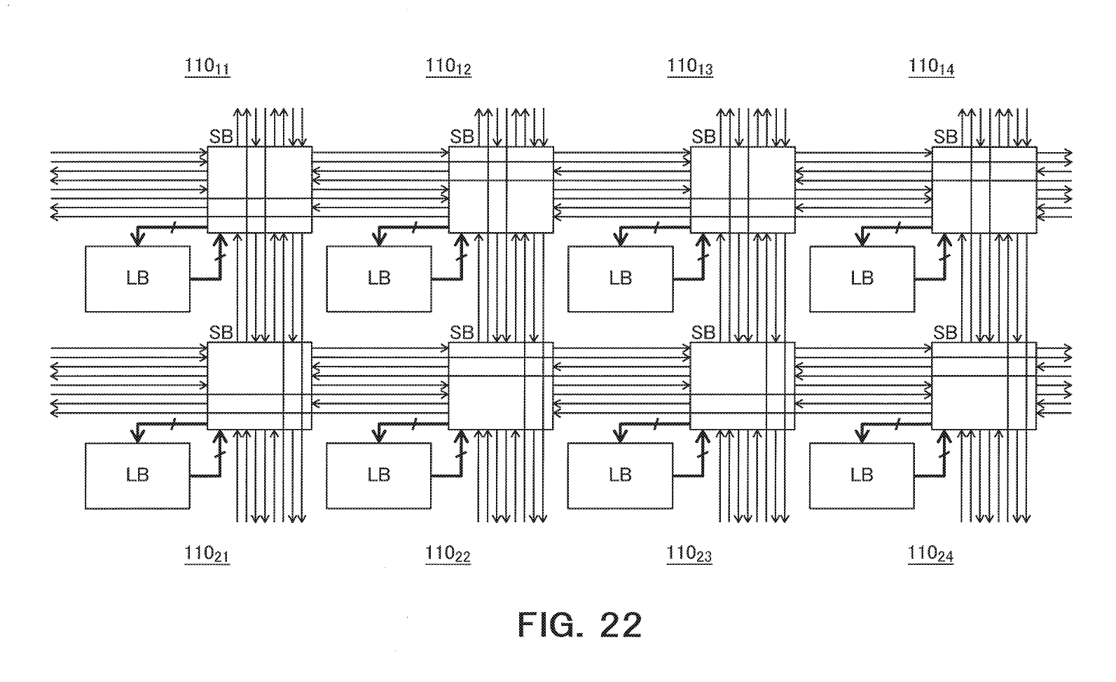

In FIGS. 18 and 19, a long-distance wiring line connects the basic tiles 110₂₁ and 110₂₄, with the two basic tiles 110₂₂ and 110₂₃ being interposed in between. However, as in an integrated circuit of a second modification shown in FIG. 21, a long-distance wiring line may be designed to connect basic tiles between which three or more basic tiles are interposed. Alternatively, as in an integrated circuit of a third modification shown in FIG. 22, long-distance wiring lines may coexist with wiring lines that connect adjacent switch blocks.

As described so far, according to the first embodiments and the modifications thereof, it is possible to provide an integrated circuit that can reduce or prevent signal delays between logic blocks.

### Second Embodiment

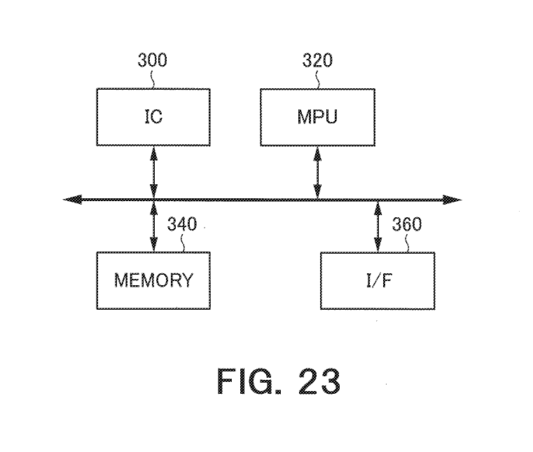

FIG. 23 shows an electronic apparatus according to a second embodiment. The electronic apparatus of the second embodiment includes a circuit 300 including the integrated circuit of any of the first embodiment and the modifications thereof, a microprocessor (hereinafter also referred to as micro-processing unit (MPU)) 320, a memory 340, and an interface (I/F) 360. These components are connected to one another via a bus line 380.

The MPU 320 operates in accordance with a program. The program for the MPU 320 to operate is stored beforehand into the memory 340. The memory 340 is also used as a work memory for the MPU 320 to operate. The I/F 360 communicates with an external device, under the control of the MPU 320.

The second embodiment can achieve the same effects as those of the first embodiment and the modifications thereof.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. An integrated circuit comprising:
first through third basic tiles, the second basic tile being located between the first basic tile and the third basic tile, each of the basic tiles including a first logic block configured to perform a logical operation and a first switch block, the first switch block including a first switch circuit, the first switch circuit including: two-terminal switch elements arranged in a matrix form; input terminals, each of the input terminals being connected to one of terminals of each of the two-terminal switch elements aligned in the same column; and output terminals, each of the output terminals being connected to the other one of the terminals of each of the two-terminal switch elements aligned in the same row;
a first wiring line connecting the first switch circuit of the first basic tile to the first logic block of the first basic tile;
a second wiring line connecting the first switch circuit of the first basic tile to the first switch circuit of the second basic tile;
a third wiring line directly connecting the first switch circuit of the first basic tile to the first switch circuit of the third basic tile;
a fourth wiring line connecting the first switch circuit of the second basic tile to the first logic block of the second basic tile;
a fifth wiring line connecting the first switch circuit of the second basic tile to the first switch circuit of the third basic tile; and
a sixth wiring line connecting the first switch circuit of the third basic tile to the first logic block of the third basic tile, wherein the third wiring line is connected to one of the input terminals of the first switch circuit of the second basic tile.

2. The integrated circuit according to claim , further comprising:
a fourth basic tile located between the second basic tile and the third basic tile, the fourth basic tile including a second logic block configured to perform a logical operation and a second switch block, the second switch block including a second switch circuit, the second switch circuit including: two-terminal switch elements arranged in a matrix; input terminals, each of the input terminals being connected to one of terminals of each of the two-terminal switch elements aligned in the same column; and output terminals, each of the output terminals being connected to the other one of the terminals of each of the two-terminal switch elements aligned in the same row;
a seventh wiring line connecting the second switch circuit of the fourth basic tile to the second logic block of the fourth basic tile;
an eighth wiring line connecting the second switch circuit of the fourth basic tile to the first switch circuit of the second basic tile; and
a ninth wiring line connecting the second switch circuit of the fourth basic tile to the first switch circuit of the third basic tile,
wherein the third wiring line is connected to one of the input terminals of the second switch circuit of the fourth basic tile.

3. The integrated circuit according to claim 1, wherein the two-terminal switch elements are gate oxide film breakdown anti-fuse elements.

4. The integrated circuit according to claim 1, wherein the two-terminal switch elements are resistive change elements.

5. An integrated circuit comprising:
a basic tile including a logic block configured to perform a logical operation and a switch block, the switch block including a switch circuit, the switch circuit including: two-terminal switch elements arranged in a matrix form; input terminals, each of the input terminals being connected to one of terminals of each of the two-terminal switch elements aligned in the same column; and output terminals, each of the output terminals being connected to the other one of the terminals of each of the two-terminal switch elements aligned in the same row; and
a wiring line connecting the switch circuit and the logic block.

6. The integrated circuit according to claim 5, wherein the two-terminal switch elements are gate oxide film breakdown anti-fuse elements.

7. The integrated circuit according to claim 5, wherein the two-terminal switch elements are resistive change elements.

8. An electronic apparatus comprising:
the integrated circuit according to claim 1;
a memory storing a program; and
a processor configured to perform processing on the integrated circuit in accordance with the program stored in the memory.
